(19) United States
(12) Patent Application Publication
(10) Pub. No.: US 2008/0211540 A1
(43) Pub. Date: Sep. 4, 2008

(54) PROGRAMMABLE ANTI-FUSE BASED ON, E.G., ZNCDS MEMORY DEVICES FOR FPGA AND OTHER APPLICATIONS

(76) Inventor: Shinobu Fujita, Inagi (JP)

Correspondence Address: WATCHSTONE P+D, PLC, 1250 CONNECTICUT AVENUE, N.W., SUITE 700, WASHINGTON, DC, 20036-2657, US

(21) Appl. No.: 12/038,807

(22) Filed: Feb. 27, 2008

Related U.S. Application Data
(60) Provisional application No. 60/892,110, filed on Feb. 28, 2007.

(51) Int. Cl. H03K 19/173

(52) U.S. Cl. 326/47

(57) ABSTRACT

According to some embodiments, an “excess-current programming method” on ZnCdS memory devices for FPGA applications is disclosed. an “excess-current programming method” can also be employed within a variety of other applications, including other memory devices having low On-resistance, such as, e.g., metal-oxide memory like Ti-oxide, Ni-oxide, W-oxide, Cu-oxide and so on. Embodiments of ZnCdS based devices (e.g., memory devices), FPGA elements incorporating the same and methods thereof for reconfigurable circuits can reduce area overhead, power overhead and/or latency (e.g., of FPGA), address a disturbance problem during logic operation, decrease an ON-resistance characteristic and/or obtain increased data retention.

### CROSS-REFERENCE TO RELATED APPLICATIONS

This application claims the benefit of U.S. Provisional Patent Application No. 60/892,110, filed on Feb. 28, 2007 in the U.S. Patent and Trademark Office, the disclosure of which is incorporated herein by reference.

### BACKGROUND OF THE INVENTION

1. Field of the Invention

The present application relates generally to memory devices, and embodiments according to the invention provide, among other things, an excess-current programming method for memory devices.

2. Background Discussion

### BACKGROUND PATENTS AND REFERENCES

The entire disclosures of each of the following background patents and/or references are incorporated herein by reference in their entireties:

a) IEEE JOURNAL OF SOLID-STATE CIRCUITS, VOL. 40, No. 1 JANUARY 2005, A Nonvolatile Programmable Solid-Electrolyte Nanometer Switch, S. Kaeriyama et al. (hereinafter, Reference [a]);

b) Resistive Switching Mechanism in ZnxCd1-xS Nonvolatile Memory Devices, by Zheng Wang, Peter B. Griffin, Jim McVittie, Simon Wong, Paul C. McIntyre, and Yoshio Nishi, IEEE ELECTRON DEVICE LETTERS, VOL. 28, NO. 1, JANUARY 2007 (hereinafter, Reference [b]);

c) Nonvolatile SRAM Cell, by Wei Wang, Aaron Gibby, Zheng Wang, Shinobu Fujita*, Peter Griffin, Yoshio Nishi, and Simon Wong, Center for Integrated Systems, Stanford University, Calif. 94305, *Frontier Research Laboratory, Toshiba Corporation (hereinafter, Reference [c]);

d) Axon Techologies' paper: Non-Volatile Memory Based on Solid Electrolytes, by Michael N. Kozicki, Chakravarthy Gopalan, Murali Balakrishnan, Mira Park, and Maria Mitkova, Center for Solid State Electronics Research Arizona State University, Tempe, Ariz. 85287-6206, USA, at http://www.axontc.com/images/Nov04NVMTSpaper.pdf. (hereinafter, Reference [d]). See also http://www.axontc.com/images/PMCNonolatileMemory.pdf.

Documents [2], [3], and [4] are also physically included within the present application and constitute part of this application.

### SUMMARY

Embodiments of the invention can significantly improve upon existing methods and/or apparatuses.

An object of the invention is to address at least the above problems and/or other disadvantages in the related art and/or to provide at least the advantages described hereinafter in whole or in part.

According to some embodiments, a reconfigurable system is provided that can include a memory device having an On-resistance lower than about one kilo-ohm. According to some examples, the memory device is a reconfigurable memory device that may be configured to be programmed using an excess current programming current. In some examples the reconfigurable memory device includes FPGA with ZnCdS based devices configured to be at least two terminal cross-point switching devices (CPDs), and a current limitation connection transistor coupled to an input of ZnCdS based devices.

According to some embodiments, a method is provided that can include performing an excess-current programming method on a low On-resistance memory device. According to some examples, the method may include performing the excess-current programming method for reconfigurable circuit applications or memory devices having metal-oxide memory including Ti-oxide, Ni-oxide, W-oxide, or Cu-oxide.

According to some embodiments, a method is provided that can include programming ZnCdS based devices for FPGA and other reconfigurable circuit applications. According to some examples, the method includes employing an excess-current programming method during said programming or employing a current limitation technique during operation. In some examples, the excess-current programming method includes flowing substantially larger current than a threshold current for Off-to-On programming through the ZnCdS based devices. In other examples, when the excess-current programming method is applied to Off-to-On programming, the threshold current for the On-to-Off programming is increased as the excess-current is increased. In yet other examples, the excess-current programming method may include increasing a stability of an On-state of the ZnCdS based devices, reducing an On-resistance of the ZnCdS switching device to less than about 150 ohms, less than 50 ohms, less than 40 ohms or less than 30 ohms, increasing a data retention time of substantially constant data levels for the ZnCdS switching devices and applying a current greater than 20 mA, greater than 30 mA or greater that 40 mA for said Off-to-On programming. In some examples, the ZnCdS based devices include a memory device having an On-resistance lower than about one kilo-ohm. In other examples, the method may include avoiding perturbation of programmed states for ZnCdS switching devices integrated with at least one CMOS circuit by applying a current reduced below a threshold level to the ZnCdS switching devices.

According to some embodiments, a system is provided that can include a reconfigurable circuit device configured with a ZnCdS switching device. According to some examples, the reconfigurable circuit device includes LSI, FPGA, CMOS FPGA, FPGA programmable interconnects, cross-point switching devices (CPDs), FPGA I/O circuits, FPGA logic blocks, FPGA memory circuits, FPGA logic circuits, logic blocks configured to implement logic circuits having multiple inputs and multiple outputs, PLAs or integrated circuits. In other examples, the ZnCdS switching device is a nonvolatile device configured to have two or more terminals. In yet other examples, the ZnCdS switching device is configured to have an On-resistance less than about 150 ohms, less than 50 ohms, less than 40 ohms or less than 30 ohms. In some examples, the ZnCdS switching device has substantially constant data retention time for at least three months or for at least six months or longer. In other examples, the ZnCdS switching device is configured with a turn-on current greater than 20 mA, greater than 30 mA or greater that 40 mA. In other examples, ZnCdS switching devices include a memory device having an On-resistance lower than about one kilo-ohm. In yet other examples, the system includes a disturbance prevention circuit coupled to the ZnCdS switching devices to reduce a current below a corresponding device threshold current level. In some examples, the system includes a CMOS FPGA, and the disturbance prevention circuit includes a current limitation device in logic blocks of the CMOS FPGA to provide a current limitation effect to the ZnCdS switching devices. In other examples, the current limitation device includes a CMOS circuit coupled to an input of the ZnCdS switching devices, and the current limitation device includes a connector transistor configured with a reduced connector transistor width that may be about a prescribed width or less, about 5 μm or less, about 1 μm or less, about ¾ μm or less, or about ½ μm or less. In yet other examples, a threshold current for the On-to-Off programming is increased as an excess-current level of an excess-current programming method applied to an Off-to-On programming is increased. In still yet other examples, the threshold current is doubled as the excess-current level of the excess-current programming method is increased.

According to some embodiments, an “excess-current programming method” for ZnCdS memory devices is disclosed. According to some embodiments, the “excess-current programming method” can also be employed within/for a variety of other applications, including other memory devices having low ON-resistance, such as, e.g., metal-oxide memory like Ti-oxide, Ni-oxide, W-oxide, Cu-oxide and so on. According to some embodiments, by way of example, the excess-current programming method, data retention over 6 months can be obtained and/or ON-resistance can also be decreased for memory devices such as ZnCdS memory devices. According to some embodiments, ZnCdS memory devices for reconfigurable circuits such as FPGA applications are disclosed. According to some embodiments, a memory device is provided that has an ON-resistance lower than “one kilo-ohm.” According to some embodiments, by way of example, data retention over 6 months can be obtained and/or ON-resistance can also be decreased for memory devices such as ZnCdS memory devices.

According to some embodiments, by way of example, ZnCdS memory devices have novel features for switching (e.g., CPD (Cross Point Device)) and/or logic for FPGA application, which can reduce area overhead, power overhead and/or latency of FPGA (e.g., drastically). According to some embodiments, by way of example, various disturbance disadvantages to occur logic operation can be addressed by a current limitation to novel FPGA circuits (e.g., CPD). According to some embodiments, by way of example, a current limitation can use CMOS transistor with a limiting width (e.g., narrow) and/or be implemented within logic blocks.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

These and/or other aspects and utilities of exemplary embodiments of the invention will become apparent and more readily appreciated from the following description of embodiments, taken in conjunction with the accompanying drawings, of which:

FIG. 1(a) is a diagrams illustrating an FPGA architecture and related art cross-point switching devices (CPD);

FIG. 1(b) is a diagrams illustrating application of nanometer-scale cross-point switching devices (CPD) to an intersection in a switch block of FPGA;

FIG. 2(a) is a diagram illustrating an embodiment of a nonvolatile switching device according to the invention;

FIG. 2(b) is a diagram illustrating an exemplary integration techniques into FPGA for an embodiment of a nonvolatile switching device according to the invention;

FIG. 2(c) is a diagram illustrating an exemplary I-V characteristic of an embodiment of a nonvolatile switching device according to the invention;

FIG. 2(b), 2(c) and 3 are diagrams that help to illustrate, among other things, the advantage of ZnCdS to CuS-CPD;

FIG. 3 is a diagram that illustrates a resistance characteristic of ZnCdS and CuS CPDs;

FIG. 4 is a diagram illustrating, among other things, exemplary disturbance test data for embodiments of ZnCdS CPD according to the invention;

FIG. 5 is a diagram illustrating an embodiment of a current limitation circuit for CMOS FPGA, among other things, according to the invention;

FIG. 6(a) is a diagram illustrating an exemplary characteristic trend for threshold current for “ON-to-OFF” programming for CPD embodiments according to the invention;

FIG. 6(b) is a diagram illustrating another embodiment of a nonvolatile switching device according to the invention;

FIG. 7 is a diagram illustrating an exemplary characteristic trend for threshold current for “ON-to-OFF” programming for embodiments according to the invention;

FIG. 8 is a diagram illustrating an exemplary resistance characteristics for CPD embodiments according to the invention; and

FIG. 9 is a diagram illustrating an exemplary LSI.

### DETAILED DESCRIPTION

While the present invention may be embodied in many different forms, the illustrative embodiments are described herein with the understanding that the present disclosure is to be considered as providing examples of the principles of the invention and that such examples are not intended to limit the invention to embodiments described herein and/or illustrated herein.

According to some embodiments, an “excess-current programming method” on ZnCdS memory devices is disclosed. According to some embodiments, an “excess-current programming method” can also be employed within/for a variety of other applications, including other memory devices having low ON-resistance, such as, e.g., metal-oxide memory like Ti-oxide, Ni-oxide, W-oxide, Cu-oxide and so on. According to some embodiments, by way of example, the excess-current programming method may obtain data retention over 6 months and/or ON-resistance can also be decreased for memory devices such as ZnCdS memory devices. According to some embodiments, ZnCdS memory devices for reconfigurable circuits such as FPGA applications are disclosed. According to some embodiments, a memory device is provided that has an ON-resistance lower than “one kilo-ohm.” According to some embodiments, by way of example, ZnCdS memory devices for reconfigurable circuits may obtain data retention over 6 months and/or ON-resistance can also be decreased.

According to some embodiments, by way of example, ZnCdS memory devices have novel features for switching (e.g., CPD (Cross Point Device)) and/or logic for FPGA application, which can reduce area overhead, power overhead and/or latency of FPGA (e.g., drastically). According to some embodiments, by way of example, various disturbance disadvantages to logic operation can be addressed by a current limitation e.g., for novel FPGA circuits. According to some embodiments, by way of example, a current limitation can use an internal device such as a CMOS transistor with a limiting dimension (e.g., width) and/or be implemented within logic blocks, e.g., for FPGA circuits.

### 1. APPLICATION OF NANOMETER-SCALE CROSS-POINT SWITCHING DEVICES TO FPGA AND ITS ISSUES

ASICs (Application Specific Integrated Circuits) utilize semiconductor devices custom built for the particular design. In contrast, Field Programmable Gate Arrays (FPGAs) are programmable semiconductor devices that are based around a matrix of uncommitted or configurable logic blocks (CLBs) connected via programmable interconnects. FPGAs can be programmed to the desired application or functionality requirements. The application of FPGA is growing in the field of Large Scale Integrated Circuits (LSI).

The CLBs can be the basic logic unit in an FPGA and although exact features vary, a CLB can include a configurable switch matrix (e.g., with 4 or 6 inputs), some selection circuitry (e.g., MUX, etc), and memory elements (e.g., simple flip-flops or more complex memory elements). The switch matrix is highly flexible and can be configured to handle logic (e.g., combinatorial), shift registers, RAM or the like.

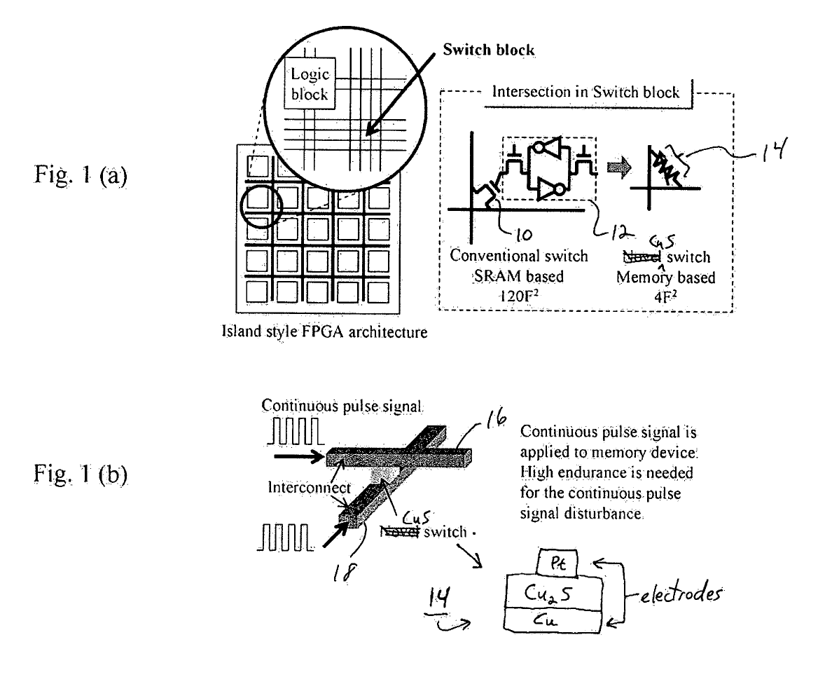

The CLB can provide the logic capability for FPGA, and flexible or programmable interconnects route the signals between CLBs and to and from I/Os. Conventional reconfigurable LSI can use FPGAs as illustrated in FIG. 1(a) that use programmable switch circuits composed of a pass transistor 10 and an SRAM-cell 12 or a flip-flop circuit to reconfigure the LSI. Reconfigurable LSI can enable a designer to change a circuit locally and avoid the need for refabrication. However, such programmable switch circuits have a high ON-resistance (e.g., 1 kΩ-2 kΩ) that can work to slow operating speeds. For example, interconnect delay between CLBs can be large because of the ON-resistance of the pass transistor is as high as several kilo-ohms. Further, such programmable SRAM switch circuits occupy a large area (e.g., 120 f²-160 f², where f² is the minimum feature size. Minimum feature size is the dimension of the smallest feature actually constructed in the manufacturing process of a chip. Since the SRAM switches are large, to reduce or minimize the number of SRAM switches, each logic cell (e.g., CLB) has a high functionality and consequently a large size. Large switches and logic cells result in a large chip size (e.g., high chip cost) and reduced cell usage efficiency.

As a large portion (e.g., over half) of a chip area of an FPGA can be occupied by a sea of SRAM-based switch circuits in the programmable interconnects, an operating speed can be mainly determined by the interconnection of the switch circuit (e.g., RC delay) rather than the gate delay of the CLBs. Such conditions can point to programmable interconnects (e.g., the switch blocks) to address or reduce the overhead of area, delay and/or power of the reconfigurable LSI and/or FPGAs.

Although FPGA has large overhead of area, delay and power compared with ASIC, its low initial development cost (e.g., non-recurring costs) and its turn around time for the circuit and system design is much shorter than that of ASIC. Further, the mask cost and lithography cost for ASIC continues to increase with the shrinking size of transistor. If the FPGA overhead of area, delay and power can be decreased, its superiority to ASIC will further increase.

FIGS. 1(a) and 1(b) are diagrams that help to illustrate, among other things, application of nanometer-scale cross-point switching devices to FPGA. As illustrated in FIG. 1(a), it has been reported that the FPGA overhead can be reduced drastically using CuS memory devices 14 as nanometer-scale cross-point switching devices (CPD). See Reference [a].

As illustrated in FIG. 1(b), a two-terminal solid electrolyte switch 14 is composed of copper sulfide (Cu₂S), which is a Cu-ionic conductor, between two electrodes (e.g., metals Cu and Pt). Since the two-terminal Cu₂S switch in FIG. 1(b) can be formed within the area of a via hole between two metal layers 16, 18 (e.g., in a switch block), the area required for its arrangement at the cross point of two wires can be as low as 4 f². Alternatively, a pass transistor can be coupled to each two-terminal Cu₂S switch to form the CPD for FPGA. In this case additional programming circuitry may be used to program the CPD (e.g., row-by-row).

The two-terminal Cu₂S switch 14 turns ON or OFF when a nanometer-scale metallic bridge either appears or disappears inside the Cu₂S layer by biasing voltages. When a negative voltage is applied to a first electrode (Pt), Cu+ ions in Cu₂S are neutralized and precipitated at the first electrode (Pt). The Cu+ ions may be supplied from the Cu electrode. The precipitated Cu can form a conductor between the two electrodes to change the conductance to an ON state. When a positive voltage is applied, the conductor (precipitated Cu ions) is ionized and dissolves, which changes the conductance to an OFF state. Each state (e.g., ON/OFF) is nonvolatile and the switching between the two states is repeatable. Also, ON-resistance of CuS memory is around 50 ohm, which is much lower than that of SRAM-based pass transistors.

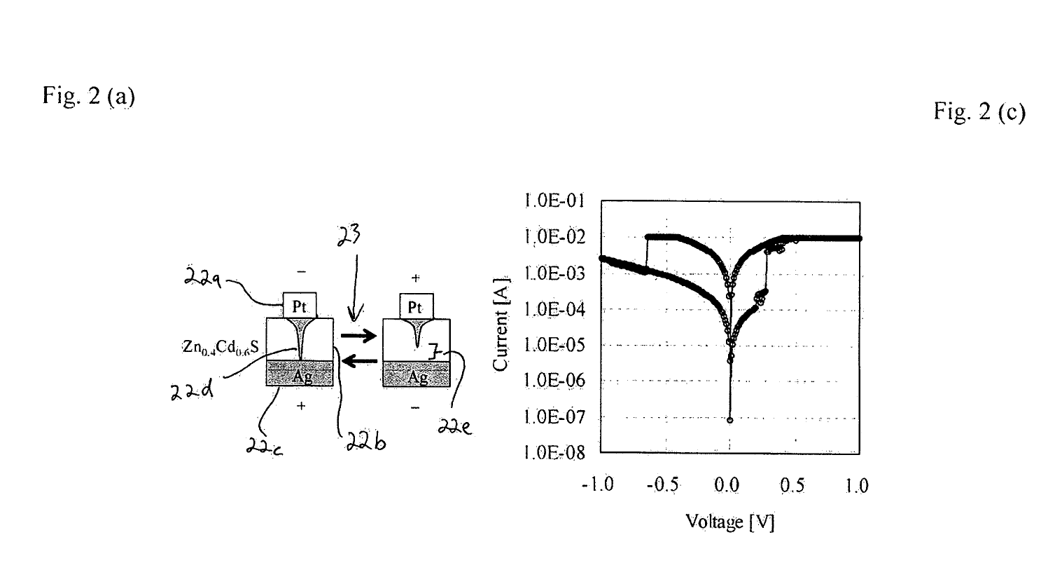

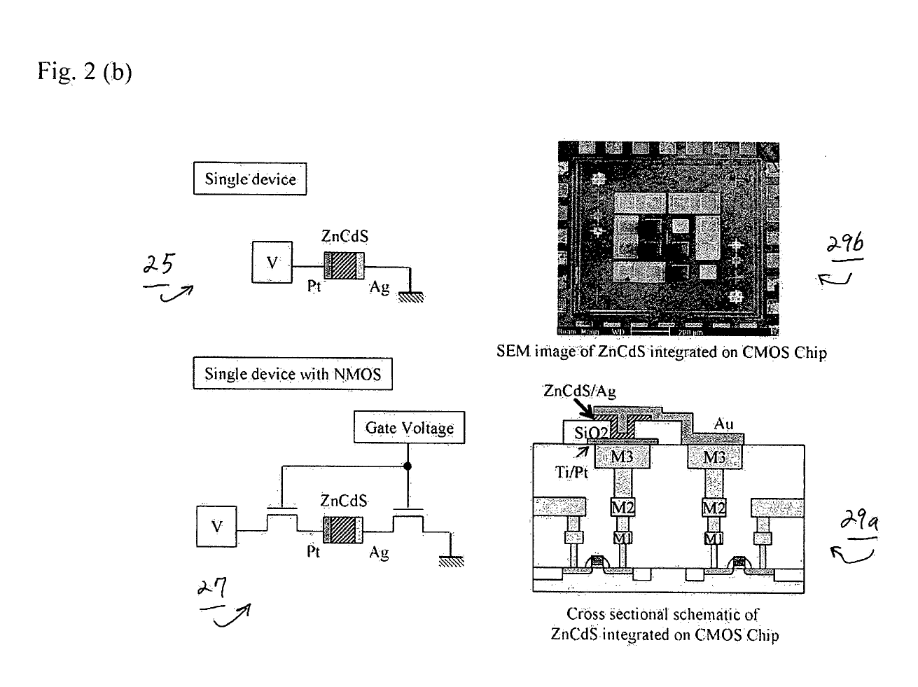

However, CuS memory device have various disadvantages to actual use for FPGA. As illustrated in FIG. 2(c), one disadvantage is that the CuS memory device switching voltage, e.g., an ON to OFF threshold voltage is less than 0.1V, and is much lower than CMOS output voltages of CMOS FPGA. The low ON to OFF threshold voltage can cause disturbances of a device state from OFF-state to ON-state of the CPD, as illustrated in FIG. 1(b). To be utilized in FPGA, for example, the CuS CPD device can be used in programmable interconnects such as connecting crossing signal lines in a switch block, which can connect logic blocks. Accordingly, signals having CMOS level output voltages can be routinely transmitted. FIG. 1(b) illustrates a continuous pulse signal being applied to the CuS memory device. Further, the CuS memory device switching voltage from OFF to ON is about 0.2V, and a switching voltage between the two states (less than 0.3 volts) should be larger than the operating voltage of the logic circuit to prevent or reduce flipping the switch on or off by applying logic signals.

Another disadvantage is short retention for the ON-state of CuS memory. After programming, ON-resistance increases gradually and can reach close to OFF-resistance levels within three months. See Reference [a]. Also, CuS has relatively large leakage current that may be caused by a low OFF-resistance, as CuS is narrow bandgap semiconductor. Since at least these disadvantages are substantial issues for FPGA applications, CuS based nanometer-scale CPD cannot be used for FPGA.

### 2. ADVANTAGES OF ZnCdS-CPD

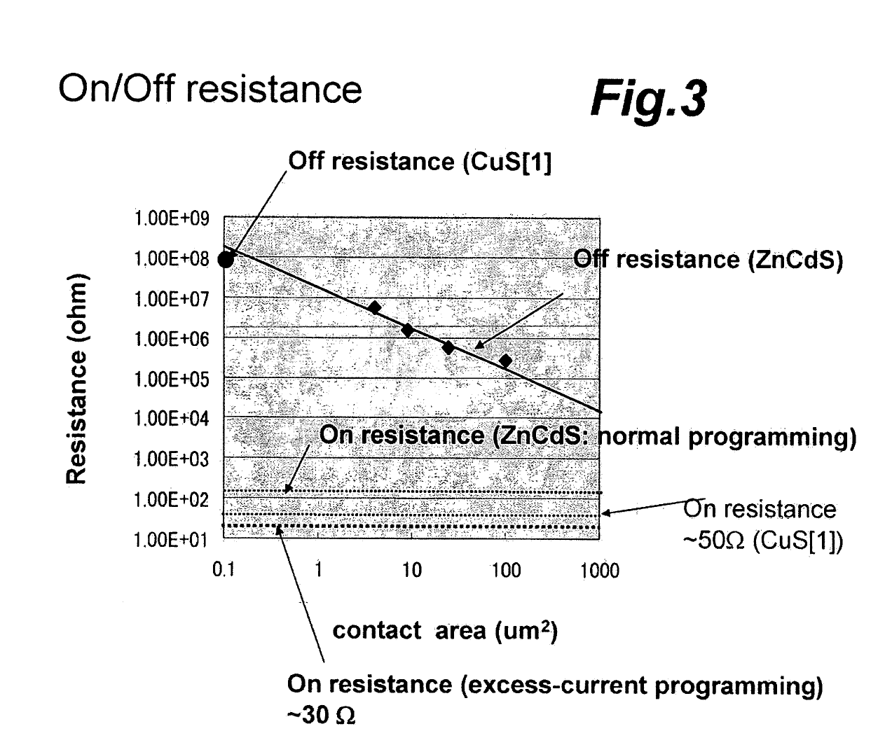

Embodiments of the invention are directed to ZnCdS based devices for FPGA (e.g., CPD). Embodiments of ZnCdS based devices according to the invention can have long term reliability and/or robustness for FPGA that may be obtained by “excess-current programming method” and/or “current limitation” technique (e.g., using CMOS transistors). ZnCdS devices have been proposed for nonvolatile memory circuits. See Reference [b] and Reference [c]. FIG. 2(a) through FIG. 3 are diagrams that help to illustrate, among other things, advantages of ZnCdS to CuS for FPGA such as CPD.

ZnCdS can be used as a solid electrolyte memory. Operations of a ZnCdS switching device is similar to devices using AgGeSe (See Reference [d]) and CuS (See Reference [a]). In operation, some metal ions migrate through the solid electrolyte film and metal can segregate at the interface of a cathode contact and the solid electrolyte film. As a result, a conductive bridge can be formed by segregation (e.g., to connect first and second electrodes).

For example, FIG. 2(a) is a diagram that illustrates a representative structure of a switching device according to one embodiment. As shown in FIG. 2(a), when a negative voltage is applied to a first electrode 22a (e.g., cathode contact), metal ions segregate and sequentially continuously deposit in the solid electrolyte film toward the second electrode 22c (e.g., anode contact). When the entire electrolyte layer or film (e.g., ZnCdS) is crossed, the switching device can change to an ON state. Such an ON state can be maintained even under a condition where power is off and a voltage not applied to the device. When a positive voltage is applied to the first electrode 22a, metal ions in the conductive bridge 22d can be ionized (e.g., absorbed within the device) until a non-conductive gap 22e appears and the switching device can change to an OFF state. Such an OFF state can be maintained even under a condition where power is off and a voltage not applied to the device. As represented using bi-directional arrows 23 in FIG. 2(a), the ZnCdS (e.g., Zn_{0.4}Cd_{0.6}S) switching device can reliably and repeatedly change between the ON and OFF states.

### ILLUSTRATIVE EXAMPLES

Exemplary cross-point devices according to embodiments were fabricated on top of FPGA test circuits developed using 0.25 μm CMOS process technology. As shown FIG. 2(b), representative two-terminal RF sputtered Zn_{0.4}Cd_{0.6}S devices 25 used a Pt bottom electrode and Ag top electrode (e.g., 3 μm×3 μm) on the top of the CMOS FPGA circuits. FIG. 2(b) illustrates an alternative configuration for a single device 27 using NMOS technology (e.g., transistors) that can be used for devices (e.g., CPDs) according to embodiments.

As illustrated in FIG. 2(b), a cross-sectional schematic view 29a of a fabricated cross-point device 25 can be implemented using a single additional metal layer M3 and can be positioned over the FPGA circuits. This configuration can reduce an overall size of FPGA circuits. However, embodiments are not intended to be so limited as exemplary ZnCdS devices could be incorporated into (e.g., within or between) selective layers of the FPGA circuits. Further, exemplary ZnCdS devices could be incorporated adjacent other FPGA circuits. A perspective view of the fabricated cross-point ZnCdS switching device integrated on a CMOS chip is illustrated in FIG. 2(b) as a scanning electron microscope (SEM) image 29b.

FIG. 2(c) is a diagram that illustrates an I-V characteristic of the fabricated cross-point ZnCdS switching device. As exemplified in FIG. 2(b), the I-V characteristic illustrates a hysteresis curve. The switching voltage from OFF to ON is approximately in the range of −0.6V, The switching voltage from ON to OFF is approximately in the range of 0.3V.

FIG. 3 is a diagram illustrating exemplary resistance characteristics of ZnCdS CPDs and CuS CPDs for comparison. As shown in FIG. 3, an ON-resistance of a ZnCdS CPD can be around 150 ohm, higher than that of CuS device (i.e., 50 ohm). An OFF resistance a ZnCdS CPD can be slightly higher than that of CuS device. While not intending to rely or be bound by any particular theory to explain such a difference, it may be attributed to a bandgap of ZnCdS, which is larger than that of CuS (i.e., 1×10⁸ ohm). The ZnCdS CPD OFF resistance can depend on device area because it is dominated by leakage current (e.g., through the ZnCdS film). However, a ZnCdS CPD ON-resistance does not depend on or can be independent of the device area since the size of the conductor (e.g., conductive bridge) formed in the electrolyte film between the electrodes is much smaller than that of the cross-point devices. See Reference [b]. As shown in FIG. 3, the ratio of OFF-resistance to ON-resistance can increase with the decreasing size of the cross-point device to reach more than the 5^{th} order (i.e., 105) in magnitude for the device area less than 1 μm². Such characteristic is highly preferable for cross-point devices since the total FPGA current consumption may strongly depend on the leakage current (e.g., OFF-resistance) at the huge number (e.g., more than one million) of the cross point devices in FPGA designs or systems.

### 3. SOLUTION FOR DISTURBANCE ISSUE OF OFF-STATE CPD

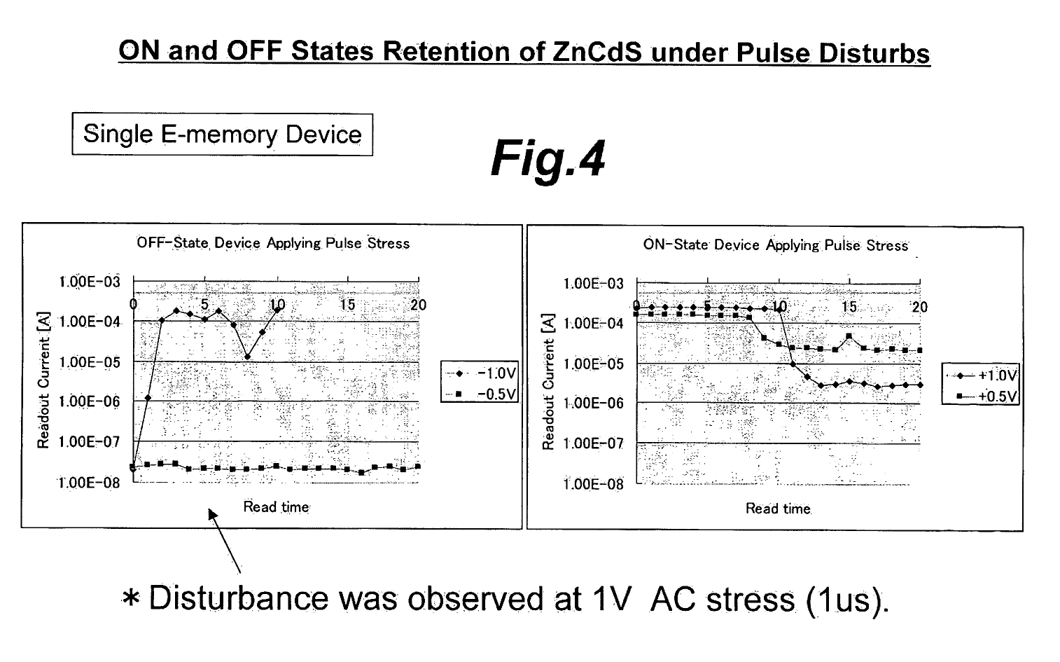

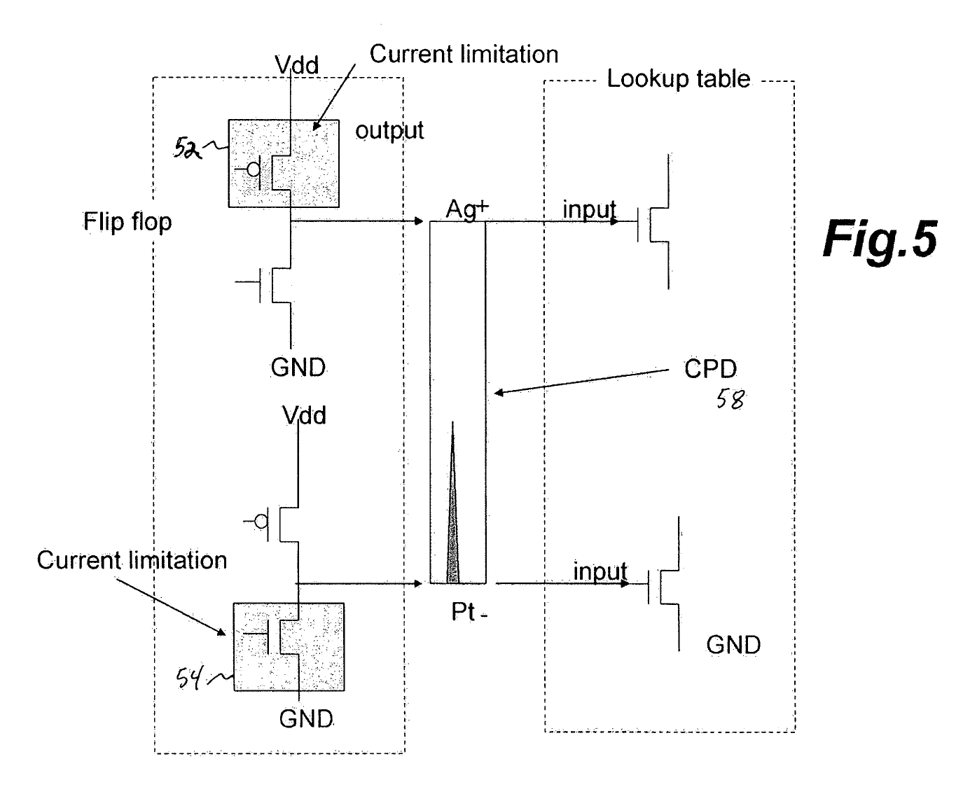

In some embodiments of the invention, an OFF-to-ON threshold voltage is around 0.3V by DC measurement as shown in FIG. 2(c). The OFF-to-ON voltage of the ZnCdS switching device may be much smaller than exemplary operating voltages of corresponding logic circuits (e.g., in the FPGA). For example, the OFF-to-ON voltage is much smaller than the supply voltage for CMOS (e.g., 0.8˜1.5V) in FPGA. FIGS. 4 and 5 are diagrams that illustrate, among other things, circuits and methods to address a disturbance issue of OFF-state CPD according to embodiments of the invention.

It is desirable for CPDs in CMOS FPGA to have high endurance to resist the exemplary continuous pulse signal illustrated in FIG. 1(a). FIG. 4 illustrates data resulting from an AC bias disturbance test (e.g., stress test) for embodiments of the ZnCdS CPD. As shown in FIG. 4, the disturbance of the OFF-state CPD state was not seen for the 0.5V pulse application with 1 μsec duration, however, the disturbance was seen for the 1V pulse application with 1 μsec duration.

To address various disadvantages including solid electrolyte devices including the disturbance issue for OFF-state CPDs, according to some embodiments, a disturbance prevention unit can be used. In some embodiments, the disturbance prevention unit can include a current limitation device. Preferably, the current limitation device can reduce a current below a threshold current for a corresponding device during operation of a reconfigurable circuit. According to the invention, even if the voltage over the threshold voltage is applied to a corresponding device, if the current is lower than the threshold current for the device, the device state cannot be changed (e.g., erroneously).

In one embodiment, disturbance prevention circuit can reduce a maximum or high current level for input signals through a CPD below a level sufficient to change the CPD device from the OFF state to an ON state, which can occur in an unprotected configuration or condition (e.g., around 10 mA for an exemplary ZnCdS device).

FIG. 5 is a diagram illustrating an embodiment of disturbance prevention circuit that can include a current limitation circuit for CMOS FPGA according to the invention. As shown in FIG. 5, the current limitation device can include at least one current limitation unit (e.g., current limitation transistors). Exemplary disturbance prevention circuit (e.g., current limitation unit for CMOS) preferably have a limiting dimension characteristic. Exemplary current limitation transistors 52, 54 can be 1 μm in width. Preferably, current limitation transistors 52, 54 can reduce a maximum current (e.g., high level current or operating current) through the CPD below the threshold current. In one embodiment, a maximum on-current (first current) of the current limitation transistor is less than a minimum current (second current) for programming ZnCdS switching devices. As shown in FIG. 5, the current limitation transistors 52, 54 reduce the current through a CPD 58 to around 60 μA, which is a much lower level than that required to change the CPD from the OFF-state to on the ON-state (e.g., around 10 mA). Accordingly, even if the voltage (e.g., CMOS FPGA voltage) over the device threshold voltage is applied to the CPD, the CPD state cannot be changed when the current is lower than the threshold current. Thus, embodiments of the disturbance prevention circuit can reduce disturbances or a state transition error occurring in the CMOS FPGA. For example, the 1V pulse 1 μsec pulse stress test did not cause an error to occur for the CPD incorporating an embodiment of the disturbance prevention circuit (e.g., “current limitation effect by CMOS”). Such a current limitation circuit can be configured (e.g., internal or external control) to be bypassed as required.

The exemplary current limitation of 60 μA was selected based on long term considerations. The exemplary current limitation of 60 μA was selected considering tolerance to disturbance for long term (e.g., over one year) and large multi-step (e.g., over one million cycle) disturbance. Therefore, the transistor width illustrated in FIG. 5 is preferably reduced as much as possible, and a width of 1 μm was selected using these criteria in this case. However, embodiments according the invention is not intended to be limited by the exemplary disclosure. For example, a transistor width can be a prescribed width or less, about 5 μm or less, about 1 μm or less, about ¾ μm or less, or about ½ μm or less, etc.

FIG. 5 illustrates an exemplary disturbance prevention circuit within logic blocks to control disturbance in the programmable interconnects between logic blocks, however, the invention is not intended to be so limited. For example, embodiments of a disturbance prevention circuit could be provided between CLBs such as for a single switch block, for a plurality of CPDs within a single switch block, for a plurality of switch blocks, or the like. Further, elements of FPGA logic blocks and/or I/O blocks incorporating embodiments of ZnCdS switching devices (e.g., multi-input LUT-based logic cell circuits, adders, multipliers, FFT compilers, FIR filters or the like) can incorporate embodiments of a disturbance prevention circuit according to the invention.

### 4. SOLUTION FOR LONG TERM RETENTION ISSUE OF ON-STATE CPD

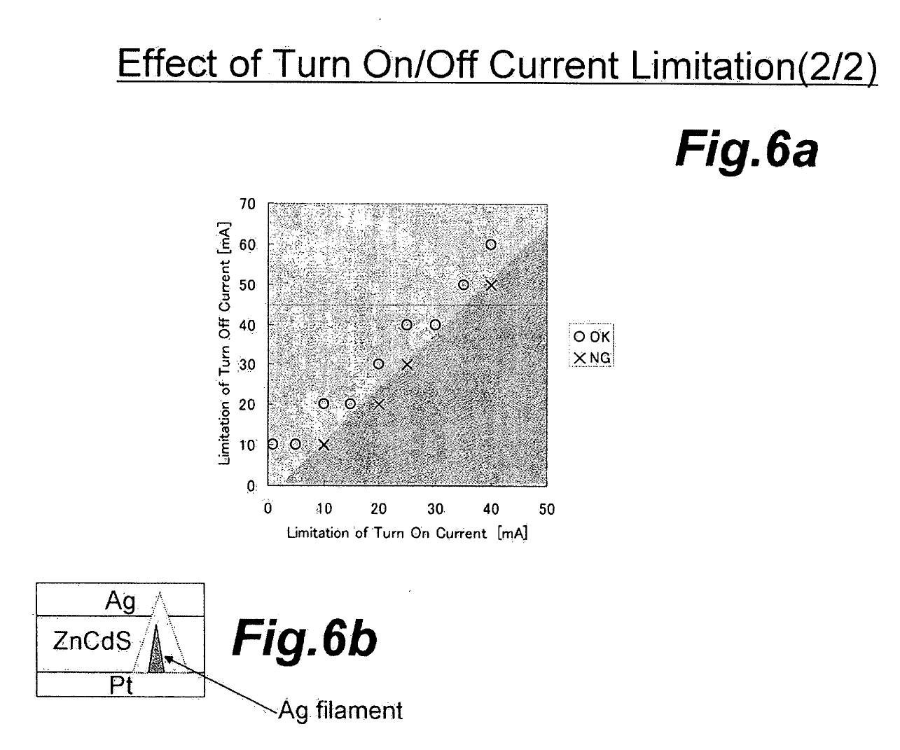

FIG. 6b) is a diagram that illustrates another embodiment of a nonvolatile switching device in accordance with the invention. Features of electrodes and a solid electrolyte film are similar to the embodiment of FIG. 2(b) and accordingly, a detailed description thereof is omitted here. However, at least a conductor formed between electrodes (e.g., a conductor bridge or filament) in a ZnCdS film or layer and/or characteristics of devices variously incorporating the embodiment of FIG. 6(b) are preferably different from the embodiment of FIG. 2(a).

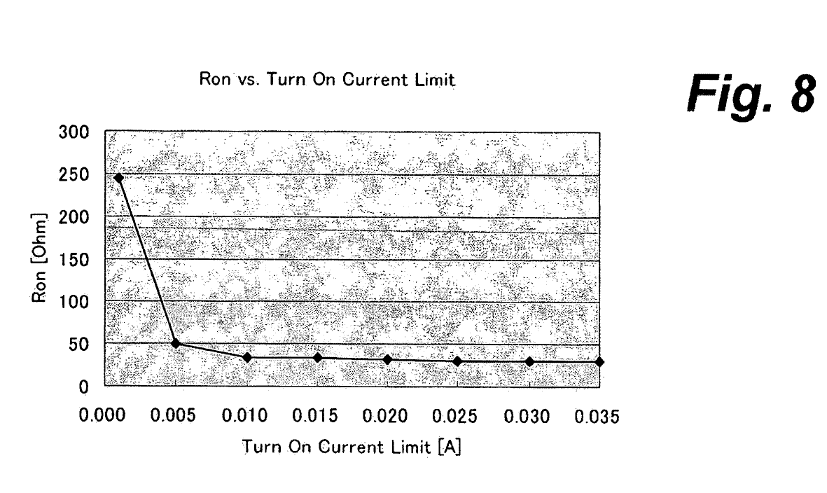

As shown in the embodiment of FIG. 6(b), a size of an Ag filament (e.g., conductor) formed in ZnCdS can be increased relative to some embodiments. Further, as shown in FIG. 8, while an ON-resistance is about 150 ohm in some embodiments (e.g., by general programming such as of a minimum current for OFF-to-ON programming or the embodiment of FIG. 2(b)), an ON-resistance of the embodiment of FIG. 6(b) can be reduced below 150 ohms. As shown in FIG. 8, an ON-resistance of at least one embodiment (e.g., 0.25 A turn on current) preferably reaches as low as approximately 30 ohms. As shown in FIG. 3, the ON-resistance of 30 ohms for one embodiment according to the invention is lower than that of a CuS switch.

In addition, a threshold current for “ON-to-OFF” programming can be increased for an embodiment of a ZnCdS switching device of FIG. 6(b). An exemplary characteristic trend showing an increasing threshold current for “ON-to-OFF” programming for embodiments according to the invention is shown in FIG. 6(a). As the “ON-to-OFF” programming threshold is increased, a stability of an ON-state for the corresponding device can be increased or improved.

An embodiment of a method for forming a nanometer-scale switching device according to the invention will now be described. For example, the method embodiment can be used to form and will be described using the embodiment of a ZnCdS switching device of FIG. 6(b). As illustrated in FIG. 6(b), the ZnCdS switching device can be formed using an excess-current programming method when configuring or “programming” corresponding programmable switch circuits, which may be used to configure or reconfigure LSI circuits or the like. For example, the “excess-current programming method” preferably operates to transmit or flow much larger current than the threshold current for OFF-to-ON programming. Generally, known circuits such as programming circuits for FPGA programmable interconnects may be used to implement embodiments of an excess-current programming method according to the invention. When the excess-current programming method is applied to “OFF-to-ON” programming, the threshold current for “ON-to-OFF” programming is increased as the excess-current is increased, which means stability of the ON-state can be improved. As described above, a trend is shown in FIG. 6(a), which illustrates an exemplary trend for the ZnCdS device of FIG. 6(b). The “excess-current programming method” may also be effective for long term data retention. For example, the “excess-current programming method” was effective to increase a data retention time of an ON-state ZnCdS based devices.

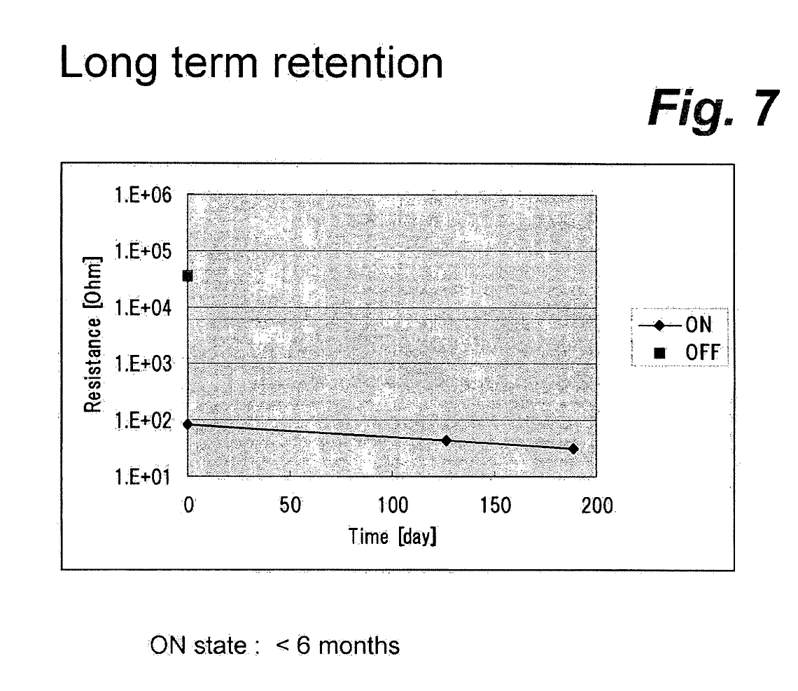

Also, FIG. 7 is a diagram that illustrates ZnCdS-CPD programmed by excess-current may have a long retention of over 6 months without evident change in ON-resistance. In contrast, an ON-resistance of CuS increases with time and finally reaches unstable or OFF-resistance levels within 3 months. See Reference [a]. Further, it was determined that an excess-current programming method was not effective to improve the retention of CuS based CPD. While not intending to rely or be bound by any particular theory to explain such a result, it may be attributed to or caused by the threshold voltage of CuS-CPD is too small and/or Ag ions are easy to migrate in the CuS film.

According to embodiments of the invention, retention of OFF-state of solid electrolyte memory based CPD can be made sufficient for use in FPGA. Further, there is no disadvantage for reliability (or a reduced disadvantage) of an OFF-state CPD according to embodiments of the invention.

Also, embodiments of the invention can use an excess-current programming method to reduce the ON-resistance of CPD. While not intending to rely or be bound by any particular theory to explain such a difference, it may be considered that the size of nanometer scale switch conductor (e.g., Ag filament) forming in ZnCdS increases with excess-programming current, as illustrated in FIG. 6b, and that ON-resistance can also be correspondingly decreased. As shown in FIG. 8, while ON-resistance for some embodiments is about 150 ohm by general programming, the ON-resistance can be reduced (down to approximately 30 ohms).

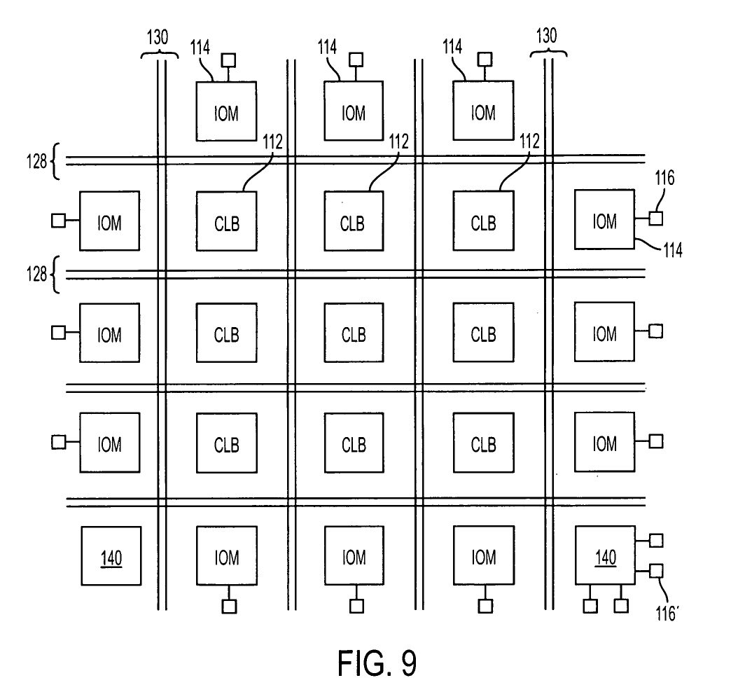

FIG. 9 is a block diagram illustrating a portion of an exemplary LSI including at least one exemplary FPGA. The exemplary FPGA can include input/output modules (IOMs), a plurality of arranged (e.g. an array) logic functions circuits (CLB) such as CLBs, resources for interconnection of the CLBs, and a configuration memory. The 10 Ms may be arranged around the perimeter of the device and provide an interface between internal components of the FPGA and external connections. The interconnect resources can connect the CLBs and 10 Ms and may include interconnect lines, programmable interconnect points (PIPs) and switching matrixes (SWs). The PIPs and switching matrixes may connect the interconnect lines to form specific paths between CLBs, or between a CLBs and an IOM. PIPs, as well as switching matrixes, may be programmed to make connections by memory cells in the configuration memory.

Each of the CLBs may be disposed in an array and include a plurality of inputs and at least one output. Thus, a plurality of logic function circuits CLBs 112 are shown. Although, nine logic function circuits arranged as a matrix of three rows and three columns are illustrated in FIG. 9, those of ordinary skill in the art will understand that arrays of arbitrary size (and/or depth) are contemplated. A variety of high performance logic circuits (e.g., multi-input LUT-based logic cell circuits, adders, multipliers, FFT compilers, FIR filters or the like may be implemented by one or more CLBs.

The FPGA may use a plurality of input/output (I/O) modules 10 Ms 114 to communicate with corresponding I/O pads 116 on the integrated circuit and to provide an interface e.g., bi-directional buffer circuits of known various configuration) between the FPGA and the outside world. As with the logic function circuits, the illustration of twelve 10 Ms is meant to be conceptual and not limiting. The number of such I/O modules and I/O pads in any given IC implementation is a function of design choice.

As illustrated in FIG. 9, a general interconnect structure disposed on the integrated circuit can include a plurality of interconnect conductors disposed within the array. An exemplary general interconnect structure is illustrated as a network of horizontal and vertical lines running in between the CLBs and the 10 Ms. For illustration, horizontal interconnect conductors are shown in groups (e.g., 4 groups) designated 128 and vertical interconnect conductors are shown in groups (e.g., 4 groups) designated 130. Those of ordinary skill in the art will recognize that conceptual and/or physical groupings of such interconnect conductors may take any of a number of forms.

The interconnect conductors may be connected to one another, to the inputs and outputs of the logic function circuits, and to the input, output, and control input nodes of the I/O modules by programming user-programmable interconnect elements. While these elements are not depicted in FIG. 9, those of ordinary skill in the art will recognize that they are typically disposed at some of the intersections of the horizontal and vertical connectors, and at the intersections of the horizontal and vertical conductors and the inputs and outputs of the logic function circuits and the I/O modules. In addition, the horizontal and vertical conductors are often segmented by user-programmable interconnect elements which, when programmed, act to selectively lengthen the conductors in a custom manner. There are several available types of user-programmable interconnect elements, including antifuse elements, transistors, and memory element transistors which may be utilized in different configurations. As described above, various embodiments according to the invention such as ZnCdS based devices may operate as programmable interconnect elements.

To program an FPGA device such as that depicted in FIG. 9, the user effects connections between the inputs and outputs of selected function circuits, and between the inputs and outputs of the CLBs and the I/O pads of the integrated circuit via the I/O modules by programming selected ones of the user-programmable interconnect elements. The particular programming scheme used will depend on the particular type of programmable element employed. Alternatively, selective direct interconnections between the inputs of selected ones of the logic function circuits and the output nodes of selected ones of the I/O modules may be used.

Programming of the exemplary FPGA (e.g., programming user-programmable interconnect elements) may be controlled by program and test control circuit 140. Program and test control circuit 140 preferably contains the necessary circuitry to accept programming data and control signals from off chip (e.g., via connected I/O pads 116′). Those of ordinary skill in the art will recognize that the number of such I/O pads necessary for any actual implementation of the FPGA or embodiments of the invention will vary according to design choice and requirements. The data and control signals are used to program selected ones of the user-programmable interconnect elements in the integrated circuit in order to define the circuit functions of the CLBs 112 and the IOM 116 and the circuit connection paths between them. Program and test control circuit 140 may also be used to provide test data to and obtain test data from the CLBs 112 as known in the art. The program and test control circuit 140 may be used to implement embodiments of excess current programming methods described herein.

### 5. CONCLUSION

Embodiments of ZnCdS based devices (e.g., memory devices), FPGA elements incorporating the same and methods thereof according to the invention can provide novel features for reconfigurable circuit applications that can reduce both area overhead, power overhead and latency (e.g., of FPGA), address a disturbance problem during logic operation, decrease an ON-resistance characteristic and/or obtain increased data retention.

While illustrative embodiments of the invention have been described herein, the present invention is not limited to the various embodiments described herein, but include any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure, the following abbreviated terminology may be employed: “e.g.” which means “for example.”

What is claimed is:

1. A reconfigurable system comprising a memory device having an On-resistance lower than about one kilo-ohm comprising at least one switching device with an On-resistance below 50 ohms.

2. The system of claim 1, wherein the memory device is a reconfigurable memory device, wherein the memory device is configured to be programmed using an excess current programming current.

3. The system of claim 2, wherein the reconfigurable memory device comprises:
FPGA to have ZnCdS based devices configured to be at least two terminal cross-point switching devices (CPDs); and
a current limitation connection transistor coupled to an input of ZnCdS based devices.

4. A method comprising performing an excess-current programming method on a low On-resistance memory device.

5. The method of claim 4, comprising performing the method for reconfigurable circuit applications or memory devices having metal-oxide memory including Ti-oxide, Ni-oxide, W-oxide, or Cu-oxide.

6. A method comprising programming ZnCdS based devices for FPGA and other reconfigurable circuit applications.

7. The method of claim 6, comprising employing an excess-current programming method during said programming or a current limitation technique during operation.

8. The method of claim 7, wherein said excess-current programming method comprises flowing substantially larger current than a threshold current for Off-to-On programming through said ZnCdS based devices.

9. The method of claim 8, wherein when the excess-current programming method is applied to Off-to-On programming, the threshold current for the On-to-Off programming is increased as the excess-current is increased.

10. The method of claim 8, wherein said the excess-current programming method comprises:
increasing a stability of an On-state of said ZnCdS based devices;
reducing an On-resistance of the ZnCdS switching device to less than about 150 ohms, less than 50 ohms, less than 40 ohms or less than 30 ohms;
increasing a data retention time of substantially constant data levels for the ZnCdS switching devices; and
applying a current greater than 20 mA, greater than 30 mA or greater that 40 mA for said Off-to-On programming.

11. The method of claim 7, wherein ZnCdS based devices comprise a memory device having an On-resistance lower than about one kilo-ohm.

12. The method of claim 6, comprising avoiding perturbation of programmed states for ZnCdS switching devices integrated with at least one CMOS circuit by applying a current reduced below a threshold level to the ZnCdS switching devices.

13. A system comprising:
a reconfigurable circuit device configured with a ZnCdS switching device.

14. The system of claim 13, wherein the reconfigurable circuit device comprises LSI, FPGA, CMOS FPGA, FPGA programmable interconnects, cross-point switching devices (CPDs), FPGA I/O circuits, FPGA logic blocks, FPGA memory circuits, FPGA logic circuits, logic blocks configured to implement logic circuits having multiple inputs and multiple outputs, PLAs or integrated circuits.

15. The system of claim 13, wherein the ZnCdS switching device is a nonvolatile device configured to have two or more terminals.

16. The system of claim 13, wherein the ZnCdS switching device is configured to have an On-resistance less than about 150 ohms, less than 50 ohms, less than 40 ohms or less than 30 ohms,
wherein the ZnCdS switching device has substantially constant data retention time for at least three months or for at least six months, and
wherein the ZnCdS switching device is configured with a turn-on current greater than 20 mA, greater than 30 mA or greater that 40 mA.

17. The system of claim 13, wherein ZnCdS switching devices comprise a memory device having an On-resistance lower than about one kilo-ohm.

18. The system of claim 17, wherein the system comprises a disturbance prevention circuit coupled to the ZnCdS switching devices to reduce a current below a corresponding device threshold current level.

19. The system of claim 18, wherein the system comprises a CMOS FPGA, wherein the disturbance prevention circuit comprises a current limitation device in logic blocks of the CMOS FPGA to provide a current limitation effect to the ZnCdS switching devices.

20. The system of claim 19, wherein the current limitation device comprises a CMOS circuit coupled to an input of the ZnCdS switching devices, wherein the current limitation device comprises a connector transistor configured with a reduced connector transistor width, and wherein a maximum On-current of the connector transistor is less than a minimum current for programming ZnCdS switching devices.

21. The system of claim 18, wherein when the excess-current programming method is applied to Off-to-On programming, a threshold current for the On-to-Off programming is increased as an excess-current level of an excess-current programming method applied to an Off-to-On programming is increased, wherein the threshold current is doubled as the excess-current level of the excess-current programming method is increased.
